(19) United States
(12) Patent Application Publication
(10) Pub. No.: US 2006/0112876 A1
(43) Pub. Date: Jun. 1, 2006

(54) Semiconductor processing apparatus

(76) Inventors: Jin Hyuk Choi, Suwon-Si (KR); Suk Chan Lee, Suwon-Si (KR)

Correspondence Address: STANZIONE & KIM, LLP, 919 18TH STREET, N.W., SUITE 440, WASHINGTON, DC, 20006, US

(21) Appl. No.: 11/154,578

(22) Filed: Jun. 17, 2005

(30) Foreign Application Priority Data
Nov. 26, 2004 (KR) 2004-98197

(51) Int. Cl. C23C 16/00; H01L 21/306; C23F 1/00

(52) U.S. Cl. 118/715; 156/345.33

(57) ABSTRACT

A semiconductor processing apparatus, designed to inject reactant gas with uniform pressure and flux therein, includes a chamber in which a process is performed, a gas supply to supply reactant gas to the chamber, a gas dispenser having a plurality of nozzles to inject the reactant gas into the chamber, and a gas distribution route formed in the gas dispenser to uniformly distribute the reactant gas supplied from the gas supply to the nozzles.

### CROSS-REFERENCE TO RELATED APPLICATIONS

This application claims the benefit under 35 U.S.C. § 119 of Korean Patent Application No. 2004-98197, filed on Nov. 26, 2004, in the Korean Intellectual Property Office, the disclosure of which is incorporated herein in its entirety by reference.

### BACKGROUND OF THE INVENTION

1. Field of the Invention

The present general inventive concept relates to a semiconductor processing apparatus, and more particularly, to a semiconductor processing apparatus which has a gas dispenser to dispense reactant gas into a chamber in a semiconductor chemical vapor deposition (CVD) process.

2. Description of the Related Art

In semiconductor processing, CVD is a chemical process for depositing a predetermined thin film of various materials on a substrate through a chemical reaction induced by application of proper activity and thermal energy to reactant gas injected into a chamber.

According to deposition conditions, and additional injection sources, CVD processes can be classified into various types, including a plasma enhanced chemical vapor deposition (PECVD) process, a low pressure chemical vapor deposition (LPCVD) process, an atmospheric pressure chemical vapor deposition (APCVD) process, a high density plasma chemical vapor deposition (HDP-CVD) process, and the like. The HDP-CVD process is a method of creating gas plasmas within the chamber by an impact of electrons having a high energy, and allowing the reactant gas to effectively react to deposit the thin film on the substrate. The HDP-CVD process has been widely used as an effective deposition method.

U.S. Pat. No. 6,486,081 discloses conventional equipment for the HDP-CVD process, which comprises a process chamber in which the HDP-CVD process is performed, a substrate support to hold a substrate in the process chamber, a gas dispenser to inject process gases into the chamber, and an exhaust device to exhaust the gas externally from the process chamber so as to maintain a vacuum of a predetermined level in the chamber.

The construction of the gas dispenser of the conventional equipment will be described in detail as follows.

The gas dispenser of the conventional equipment comprises a gas dispenser ring to dispense the gas from a side surface of the chamber, and a gas feeder to supply the gas from an upper center portion of the chamber. The gas dispenser ring is made of aluminum or other appropriate materials. The gas dispenser ring is provided with a plurality of ports to receive a plurality of nozzles, a plurality of channels (or paths) respectively communicated with the ports, and at least one ring-shaped gas channel to dispense the gas to the channels. Two or more gas channels are provided separately from each other in order to independently dispense two or more types of gas to the paths. The gas dispenser further comprises a gas supply provided at the outside of the chamber to supply the gas to the gas channel. After being introduced into the gas channel through one port of the gas channel, the reactant gas supplied from the gas supply is distributed along the entire circumference of the gas channel, and is then injected into the chamber through the nozzles equipped in the respective ports.

However, with such a construction as described above, there is a problem in that the pressure and the flux of the gas introduced into the chamber are high at the nozzles near to the gas supply, but low at the nozzles far from the gas supply, causing non-uniform pressure and flux of the gas to be injected from the nozzles. The non-uniform pressure and flux of the gas can result in non-uniform formation of a deposition film upon a substrate, thereby causing defective products.

### SUMMARY OF THE INVENTION

The present general inventive concept provides a semiconductor processing apparatus designed to inject reactant gas at a uniform pressure and flux from respective nozzles into a chamber.

Additional aspects and/or advantages of the general inventive concept will be set forth in part in the description which follows and, in part, will be obvious from the description, or may be learned by practice of the general inventive concept.

The foregoing and/or other aspects and advantages of the present general inventive concept are accomplished by providing a semiconductor processing apparatus including a chamber in which a process is performed, a gas supply to supply reactant gas to the chamber, a gas dispenser having a plurality of nozzles to inject the reactant gas into the chamber, and a gas distribution route formed in the gas dispenser to uniformly distribute the reactant gas supplied by the gas supply to the nozzles.

The gas distribution route may comprise two or more channels to uniformly distribute the reactant gas supplied by the gas supply and a plurality of ports connecting the channels.

The number of ports connecting the channels near the nozzles may be increased from the number of ports connecting the channels near the gas supply.

The foregoing and/or other aspects and advantages of the present general inventive concept are also achieved by providing a semiconductor processing apparatus including a gas supply to supply reactant gas into a chamber, a ring-shaped gas dispenser constituting a portion of a side surface of the chamber, a plurality of gas nozzles arranged in a radial direction on an inner surface of the gas dispenser, and a gas distribution route formed in the gas dispenser to uniformly dispense the reactant gas supplied from the gas supply to the nozzles.

The gas distribution route may comprise a plurality of circular channels and a plurality of ports connecting the channels.

The number of ports connecting the channels may be increase as the channels progress toward the gas nozzles from the the gas supply.

The ports may be arranged such that ports connecting one of the channels to different adjacent channels do not align.

The semiconductor processing apparatus may further comprise two or more gas supplies and a plurality of gas distribution routes corresponding to the gas supplies, respectively.

### BRIEF DESCRIPTION OF THE DRAWINGS

These and/or other aspects and advantages of the general inventive concept will become apparent and more readily appreciated from the following description of the embodiments, taken in conjunction with the accompanying drawings, of which:

FIG. 1 is a schematic diagram illustrating a semiconductor processing apparatus according to an embodiment of the present general inventive concept;

FIG. 2 is an enlarged view illustrating a section A of the semiconductor processing apparatus of FIG. 1;

FIG. 3 is a conceptual diagram illustrating a gas distribution route of the semiconductor processing apparatus of FIG. 1;

FIG. 4 is a perspective view illustrating a plate constituting a component of the gas distribution route of the semiconductor processing apparatus of FIG. 1; and

FIG. 5 is a conceptual diagram of a gas distribution route of a semiconductor processing apparatus according to another embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings. The embodiments are described below to explain the present general inventive concept while referring to the figures.

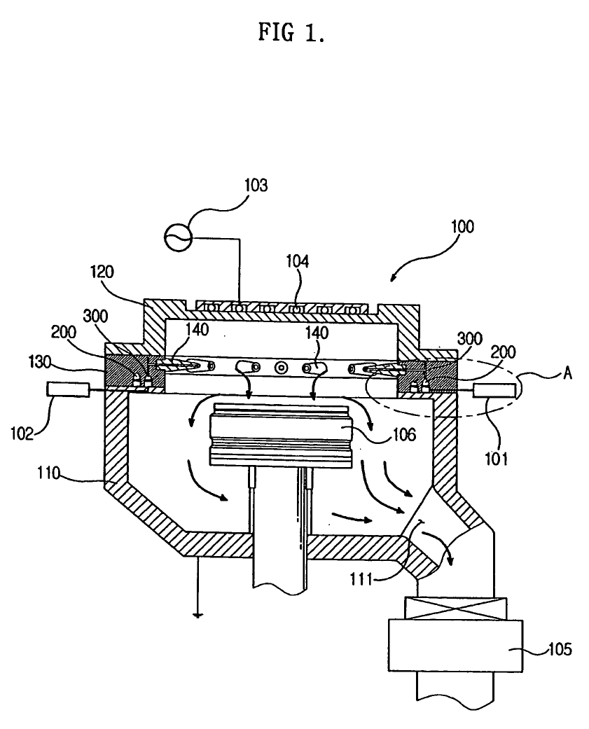

FIG. 1 illustrates a semiconductor processing apparatus according to an embodiment of the present general inventive concept. Referring to FIG. 1, the semiconductor processing apparatus comprises a chamber 100 in which a process is performed, a substrate support 106 to support a substrate while the process is performed, reactant gas supplies 101 and 102 to supply reactant gases to the chamber 100, a radio-frequency (RF) power supply 103 to supply RF power in order to excite the reactant gases into a plasma state.

The chamber 100 comprises a cylindrical chamber body 110 opened at an upper portion thereof, a cover 120 sealing the upper portion of the chamber body 110, and a gas dispenser 130 equipped at an upper end of the chamber body 110 to inject the reactant gases into the chamber 100. The chamber body 110 is grounded and has an exhaust port 111 formed at a lower portion of the chamber body 110. The exhaust port 111 is connected to a vacuum pump 105 to discharge the gas externally from the chamber 100 during the process. An RF coil 104 is provided at an upper surface of the cover 120 to create an electric field within the chamber 100 while receiving the RF power from the RF power supply 103.

A plurality of nozzles 140 are arranged in a radial direction on an inner surface of the gas dispenser 130, and one or more gas distribution routes 200 and 300 are formed in the gas dispenser 130 to uniformly distribute the reactant gases supplied from the reactant gas supplies 101 and 102 to the respective nozzles 140.

The semiconductor processing equipment illustrated in FIG. 1 has two of the reactant gas supplies 101 and 102, which supply different reactant gases, respectively. For convenience of description, the reactant gas supplies 101 and 102 are referred to as a first reactant gas supply 101 and a second reactant gas supply 102. Moreover, the gas distribution routes 200 and 300 are also referred to as a first gas distribution route 200 and a second gas distribution route 300 corresponding to the first and second reactant gas supplies 101 and 102, respectively. The first gas distribution route 200 can be located further outward along the gas dispenser with respect to the second gas distribution route 300, as illustrated in FIG. 1.

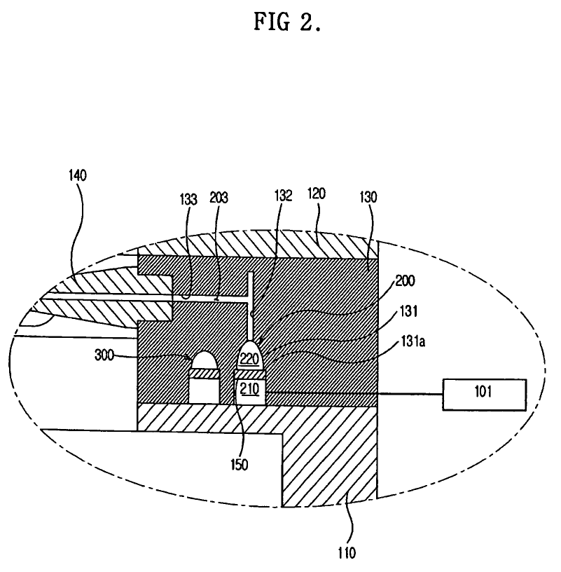

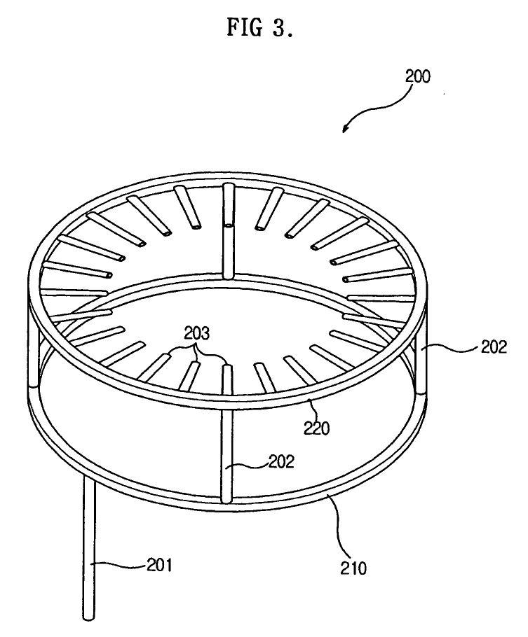

The first and second gas distribution routes 200 and 300 have an identical construction. FIG. 2 illustrates a section A of the apparatus of FIG. 1 including the first and second gas distribution routes 200 and 300. FIG. 3 is a conceptual diagram of the first gas distribution route 200. The construction of the gas distribution routes 200 and 300 will now be described with reference to FIGS. 2 and 3.

Referring to FIG. 3, the first gas distribution route 200 comprises a gas inlet 201 through which the reactant gas is introduced from the first reactant gas supply 101, a first ring-shaped channel 210 to uniformly distribute the introduced reactant gas around an entire circumference of the gas dispenser 130, a second channel 220 having the same construction as that of the first channel 210 and provided above the first channel 210, four ports 202 connecting the first and second channels 210 and 220 to each other, and a plurality of paths 203 communicating with the second channel 220 to supply the reactant gas to the respective nozzles 140. After being introduced through the gas inlet 201, the reactant gas is distributed in the first channel 210, and is then introduced to the second channel 220 through the four ports 202. The reactant gas in the second channel 220 is then distributed to the respective paths 203 and injected into the chamber 100.

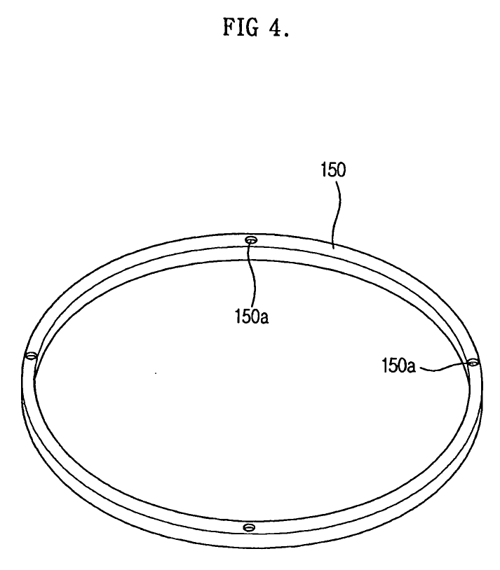

Referring to FIG. 2, the gas dispenser 130 has a ring shape, and has constant thickness and height. The gas dispenser 130 is formed with a space 131 at a lower surface thereof having a dome-shaped cross-section to allow the first gas distribution route 200 to be formed therein. The space 131 has a step 131a such that the space 131 increases in width as it progresses downwardly. A ring-shaped plate 150 is placed on the step 131a to separate the space 131 into an upper portion and a lower portion. The lower portion of the space 131 below the plate 150 is formed with the first channel 210, and the upper portion of the space 131 above the plate 150 is formed with the second channel 220. Referring to FIG. 4, four holes 150a are formed through the plate 150 to communicate the first channel 210 with the second channel 220 by accommodating the four ports 202, respectively. The plate 150 can be fixed around the step 131a by welding, caulking, or the like. A groove 132 vertically extends from an upper end of the space 131, and connects to a hole 133 extending in the radial direction of the gas dispenser 130 above the space 131. The groove 132 and the hole 133 constitute the path 203 of the first gas distribution route 200. The second gas distribution route 300 has substantially the same construction as that of the first gas distribution route 200, and therefore a detailed description thereof is omitted.

Unlike the conventional semiconductor processing equipment, in the semiconductor processing equipment of FIG. 1, the reactant gas supplied from the first gas supply 101 is not directly dispensed to the nozzles, but rather is indirectly distributed to the nozzles 140 through the first channel 210, the second channel 220, and the four ports 202 communicating between the first and second channels 210 and 220 so as to uniformly distribute the reactant gas to the nozzles 140, and is then injected into the chamber 100 through the nozzles 140. Accordingly, uniform pressure and flux of the reactant gas injected from the respective nozzles 140 is achieved.

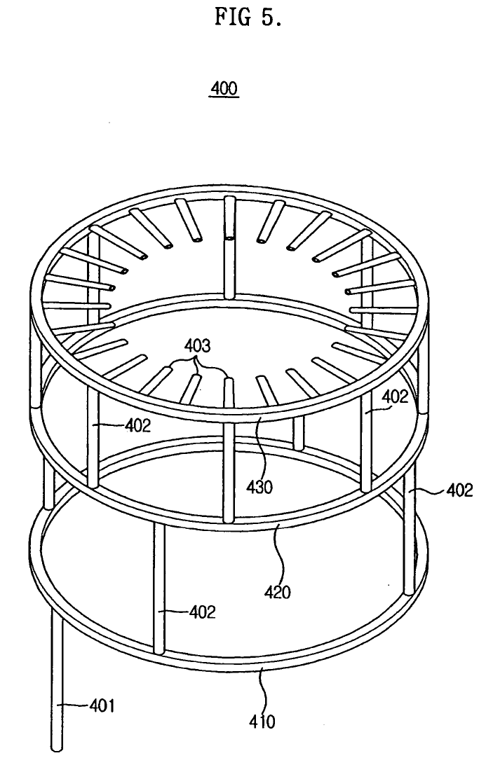

Meanwhile, when the numbers of channels and ports constituting the gas distribution route are appropriately controlled, the uniformity of the pressure and the flux of the gas injected from the nozzles can be further increased. Accordingly, FIG. 5 illustrates a gas distribution route according to another embodiment of the present general inventive concept.

The gas distribution route 400 illustrated in FIG. 5 comprises a gas inlet 401, ring-shaped first, second and third channels 410, 420 and 430, positioned respectively from bottom to top, four ports 402 connecting the first channel 410 and the second channel 420, eight ports 402 connecting the second channel 420 and the third channel 430, and a plurality of paths 403 to supply reactant gas to respective nozzles 140. The number of ports 402 connecting the channels 410, 420 and 430) increases as the channels 410, 420 and 430 progress toward the nozzles 140 from the gas inlet 401. For example, as illustrated in FIG. 5, the number of ports 402 connecting the second and third channels 420 and 430 is greater than the number of ports connecting the first and second channels 410 and 420. Upper and lower ports 402 of connected to a channel (i.e. the second channel 420) are arranged not linearly but alternately. As a result, in comparison to the gas distribution route 200 of FIG. 3, the gas distribution route 400 of FIG. 5 has increased numbers of channels and ports 402, so that the uniformity of the pressure and the flux of the reactant gas supplied to the respective nozzles 140 can be further increased.

Without being limited to the embodiments as described above, the numbers of channels and ports in a gas distribution route according to the present general inventive concept can be changed according to an interior shape of the chamber or pressure in the chamber such that the pressure and flux of the gas have optimal uniformity.

As apparent from the above description, semiconductor processing equipment according to the embodiments of the present general inventive concept has a gas distribution route to provide uniform pressure and flux of gas supplied into a chamber, thereby increasing uniformity and yield of a semiconductor wafer processed therein.

Although a few embodiments of the present general inventive concept have been shown and described, it would be appreciated by those skilled in the art that changes may be made in the embodiments without departing from the principles and spirit of the general inventive concept, the scope of which is defined in the claims and their equivalents.

What is claimed is:

1. A semiconductor processing apparatus, comprising:
a chamber in which a process is performed;
a gas supply to supply reactant gas to the chamber;
a gas dispenser having a plurality of nozzles to inject the reactant gas into the chamber; and
a gas distribution route formed in the gas dispenser to uniformly distribute the reactant gas supplied by the gas supply to the nozzles.

2. The semiconductor processing apparatus according to claim 1, wherein the gas distribution route comprises two or more channels to uniformly distribute the reactant gas supplied by the gas supply, and a plurality of ports connecting the channels to each other.

3. The semiconductor processing apparatus according to claim 2, wherein the number of ports connecting the channels increases as the channels progress toward the plurality of nozzles from the gas supply.

4. A semiconductor processing apparatus, comprising:
at least one gas supply to supply reactant gas into a chamber;
a ring-shaped gas dispenser constituting a portion of a side surface of the chamber;
a plurality of gas nozzles arranged in a radial direction on an inner surface of the gas dispenser; and
at least one gas distribution route formed in the gas dispenser to uniformly distribute the reactant gas supplied from the gas supply to the nozzles.

5. The semiconductor processing apparatus according to claim 4, wherein the gas distribution route comprises a plurality of circular channels and a plurality of ports connecting the channels.

6. The semiconductor processing apparatus according to claim 5, wherein the number of ports connecting the channels increases as the channels progress toward the plurality of gas nozzles from the gas supply.

7. The semiconductor processing apparatus according to claim 5, wherein ports connecting one of the plurality of channels to adjacent channels on the upper and lower side of the channel are not aligned.

8. The semiconductor processing apparatus according to claim 4, wherein the at least one gas supply comprises two or more gas supplies, and the at least one gas distribution route comprises two or more gas distribution routes corresponding to the gas supplies, respectively.

9. A semiconductor processing apparatus, comprising:
a chamber including upper and lower portions;
a gas dispenser disposed between the upper and lower portions of the chamber and including plural nozzles to inject reactant gas into the chamber; and
at least one gas distribution route including plural consecutive channels to uniformly distribute a reactant gas to the gas dispenser.

10. The semiconductor processing apparatus according to claim 9, wherein the at least one gas distribution route is provided within the gas dispenser and comprises:
a first channel extending through the gas dispenser;
a second channel positioned above the first channel and extending through the gas dispenser; and
a plurality of first ports communicating reactant gas between the first and second channels.

11. The semiconductor processing apparatus according to claim 10, wherein the at least one gas distribution route further comprises:
a third channel positioned above the second channel and extending through the gas dispenser; and
a plurality of second ports communicating reactant gas between the second and third channels, the plurality of second ports being alternately positioned with respect to the plurality of first ports.

12. The semiconductor processing apparatus according to claim 9, further comprising:
a reactant gas supply to supply reactant gas to the at least one gas distribution route.

13. The semiconductor processing apparatus according to claim 11, wherein the at least one gas distribution route comprises first and second gas distribution routes.

14. The semiconductor processing apparatus according to claim 10, wherein the second channel communicates the reactant gas from the first channel to the gas dispenser.

15. The semiconductor processing apparatus according to claim 11, wherein the thir channel communicates the reactant gas from the second channel to the gas dispenser and the second channel receives the reactant gas from the first channel.

16. A semiconductor processing apparatus, comprising:
a reaction chamber;
a gas supply to supply gas;
a plurality of nozzles to deposit the gas into the reaction chamber;
a plurality of gas distribution channels to uniformly distribute the gas supplied by the gas supply around a circumference of the reaction chamber; and
a nozzle communication channel communicating with the plurality of gas distribution channels and the nozzles to transfer the distributed gas to the plurality of nozzles.

17. The semiconductor processing apparatus according to claim 16, further comprising:
a plurality of ports connecting the plurality of gas distribution channels, and connecting one of the gas distribution channels to the nozzle communication channel.

18. The semiconductor processing apparatus according to claim 16, wherein the plurality of gas distribution channels are vertically spaced apart and the nozzle communication channel is disposed above an uppermost one of the plurality of gas distribution channels.

19. A semiconductor processing apparatus, comprising:
a cylindrical reaction chamber;
a plurality of gas supplies to supply a plurality of reactant gases; and
a plurality of gas distribution units to uniformly distribute the reactant gases supplied by the gas supplies, each gas distribution unit comprising:
a gas inlet to communicate with the respective gas supply to introduce the respective reactant gas supplied by the respective gas supply;
a plurality of ring-shaped channels disposed around a circumference of the cylindrical reaction chamber to uniformly distribute the respective reactant gas around the circumference of the cylindrical reaction chamber; and
a plurality of nozzles disposed around the circumference of the cylindrical reaction chamber and communicating with one of the plurality of ring-shaped channels to deposit the uniformly distributed respective reactant gas into the cylindrical reaction chamber such that the respective reactant gas is distributed uniformly through each of the nozzles.

20. The semiconductor processing apparatus according to claim 19, wherein each gas distribution unit further comprises:
a plurality of ports connecting the plurality of ring-shaped channels to communicate the respective reactant gas between the plurality of ring-shaped channels; and
a plurality of ring-shaped plates, each ring-shaped plate disposed between two of the ring-shaped channels and comprising a plurality of holes to accommodate the plurality of ports.

21. The semiconductor processing apparatus according to claim 19, wherein each gas distribution unit comprises:
a plurality of paths corresponding to the plurality of nozzles, each path connecting the respective nozzle to the one of the plurality of ring-shaped channels to communicate the respective reactant gas between the ring-shaped channel and the nozzle.
